(19) United States
(12) Patent Application Publication
(10) Pub. No.: US 2013/0126870 A1
(43) Pub. Date: May 23, 2013

(54) Thin Film Transistor, Array Substrate, Device and Manufacturing Method

(71) Applicant: Hao Kou, Shenzhen (CN)

(72) Inventor: Hao Kou, Shenzhen (CN)

(21) Appl. No.: 13/376,188

(22) PCT Filed: Dec. 2, 2011
(86) PCT No.: PCT/CN11/83338

§ 371 Date: Dec. 4, 2011

(30) Foreign Application Priority Data
Nov. 23, 2011 (CN) 201110375847.4

(51) Int. Cl. H01L 29/786; H01L 21/336; H01L 21/31

(52) U.S. Cl. 257/59; 257/57; 438/758; 438/158; 257/E29.273; 257/E21.24; 257/E21.411

(57) ABSTRACT

The present invention discloses a TFT, an array substrate, a device and a manufacturing method. The TFT comprises a conductive metal layer; an insulting oxidizing layer is formed on the surface of the metal layer. In the present invention, because the oxidation treatment is conducted on the surface of the metal layer, the insulating oxidizing layer is formed and can substitute for the silicon nitride as a TFT barrier layer; compared with the preparation of a silicon nitride barrier layer needing the drilling crew and the material cost, the preparation of the oxidizing layer needs cheap equipment without increasing further materials so that the cost is saved; in addition, the oxidizing layer only exists on the surface of the metal layer, and has small obstruction for light and low requirement for the penetration rate; thus, the process control is relatively simple and the cost can be further reduced.

### TECHNICAL FIELD

The present invention relates to the field of liquid crystal displays, and more particularly to a thin film transistor (TFT), an array substrate, a device and a manufacturing method.

### BACKGROUND

The LCD device includes an array substrate which is provided with the TFT, and a color filter plate which is provided with a public electrode. A current array substrate is generally manufactured by conventional four or five manufacturing processes of a light cover; after a multilayer film is adopted and deposited, a corresponding figure is etched in a corresponding film layer through a yellow-light technology; the multilayer film is repeatedly deposited in a plurality of chambers of physical vapor deposition (PVD) and plasma enhanced chemical vapor deposition (PECVD); then, each layer is correspondingly etched; the technology adopted currently has several defects:

1. complex technological process: after a metal layer is manufactured, nonmetal layer shall be prepared to perform the actions of impeding short circuit in metal and protecting the metal layer; a drilling crew and material cost are needed for manufacturing a nonmetal barrier layer; because the nonmetal layer is integrally covered, the requirement for light penetration is higher and accordingly, higher requirements for process control are put forward;

2. high equipment investment: each layer of film shall be individually formed; PVD, PECVD and the like need multiple chambers so that the equipment investment is enhanced;

3. heavy metal pollution: Mo metal widely adopted currently is heavy metal and has larger influence on the environment.

### SUMMARY

The aim of the present invention is to provide a TFT, an array substrate, a device and a manufacturing method with simple technology and low cost.

The aim of the present invention is achieved by the following technical schemes.

The TFT comprises a conductive metal layer; an insulting oxidizing layer is formed on the surface of the metal layer.

Preferably, the metal layer is Al and the oxidizing layer is Al2O3. This is an embodiment of materials of the metal layer and the oxidizing layer; Al2O3 is used as the oxidizing layer and has good insulating property; the dielectric constant of Al2O3 is close to that of the existing silicon nitride; Al2O3 is suitable for substituting for the silicon nitride as insulating material among metal layers.

Preferably, the metal layer is one or more of a gate electrode, a source electrode and a drain electrode of the TFT. This is a concrete form of the metal layer.

An array substrate comprises the aforementioned TFT.

A liquid crystal display (LCD) device comprises the aforementioned array substrate.

A TFT manufacturing method comprises step A: processing the insulating oxidizing layer on the surface of the metal layer of the TFT array substrate.

Preferably, in the step A, the oxidizing layer is manufactured by a microarc oxidation method. Microarc oxidation is generally used for forming a compact oxidizing layer on a metal surface for enhancing wear resistant characteristic and corrosion resistant characteristic of the metal, and is frequently used for vitrification treatment of the internal surface of an automobile engine cylinder. The inventor researches and finds that the compact ceramic layer has good insulating property, can be used as a production method of a concrete oxidizing layer and also has simple technology and lower cost.

Preferably, in the step A, surface grains of the metal layer are completely oxidized by extending the action time of an electrolytic solution to form the compact oxidizing layer. The compact oxidizing layer can be firmly fixed on the surface of the metal layer so that the compact oxidizing layer is difficult to drop and has better insulating effect.

Preferably, in the step A, the metal layer is one or more of a gate electrode, a source electrode and a drain electrode of the TFT. This is a concrete form of the metal layer.

Preferably, the metal layer is Al and the oxidizing layer is Al2O3. This is an embodiment of materials of the metal layer and the oxidizing layer; Al2O3 is used as the oxidizing layer and has good insulating property; the dielectric constant of Al2O3 is close to that of the existing silicon nitride; Al2O3 is suitable for substituting for the silicon nitride as insulating material among metal layers.

A TFT manufacturing method comprises the following steps:

A1: forming a metal TFT gate electrode on the glass substrate;

A2: adopting the microarc oxidation method to form the insulating oxidizing layer on the metal surface of the gate electrode;

A3: continuously depositing an amorphous silicon layer and a doped amorphous silicon layer on the oxidizing layer of the gate electrode;

A4: forming the source electrode and the drain electrode of the metal TFT on the doped amorphous silicon layer;

A5: adopting the microarc oxidation method for forming insulating oxidizing layers respectively on the metal surfaces of the source electrode and the drain electrode. This is a specific technical proposal of oxidation treatment on the surfaces of all of the gate electrode, the source electrode and the drain electrode of the TFT.

In the present invention, because the oxidation treatment is conducted on the surface of the metal layer, the insulating oxidizing layer is formed and can substitute for the silicon nitride as a TFT barrier layer; compared with the preparation of a silicon nitride barrier layer needing the drilling crew and the material cost, the preparation of the oxidizing layer needs cheap equipment without increasing further materials so that the cost is saved; in addition, the oxidizing layer only exists on the surface of the metal layer, and has small obstruction for light and low requirement for the penetration rate; thus, the process control is relatively simple and the cost can be further reduced.

### BRIEF DESCRIPTION OF FIGURES

FIG. 1 is a schematic diagram of a TFT in the present invention;

FIG. 2 is a schematic diagram of step 1 of a TFT manufacturing method in the present invention;

FIG. 3 is a schematic diagram of step 2 of a TFT manufacturing method in the present invention;

FIG. 4 is a schematic diagram of step 3 of a TFT manufacturing method in the present invention;

FIG. 5 is a schematic diagram of step 4 of a TFT manufacturing method in the present invention;

FIG. 6 is a schematic diagram of step 5 of a TFT manufacturing method in the present invention;

FIG. 7 is a schematic diagram of step 6 of a TFT manufacturing method in the present invention;

FIG. 8 is a schematic diagram of step 7 of a TFT manufacturing method in the present invention;

Wherein: 1. glass substrate; 2. gate electrode; 3. first ceramic layer; 4. amorphous silicon layer; 5. doped amorphous silicon layer; 6. source electrode; 7. drain electrode; 8. second ceramic layer; 9. contact window; 10. pixel electrode.

### DETAILED DESCRIPTION

The present invention will further be described in detail in accordance with the figures and the preferred examples.

An LCD device comprises an array substrate which comprises a TFT.

As shown in FIG. 1, the TFT is arranged on the glass substrate 1; the glass substrate 1 is successively provided with the gate electrode 2, the metal oxidizing layer generated by treating metal for the gate electrode 2 (i.e. the first ceramic layer 3), the amorphous silicon layer 4, the doped amorphous silicon layer 5, the source electrode 6, the drain electrode 7, the metal oxidizing layer generated by treating the metal layers of the source electrode/drain electrode 7 (i.e. the second ceramic layer 8), the contact window 9 and the pixel electrode 10. The pixel electrode 10 is connected with the drain electrode 7 through the contact window 9; the gate electrode 2, the source electrode 6 and the drain electrode 7 are metal layers; the first ceramic layer 3 and the second ceramic layer 8 are oxidizing layers formed on the surfaces of the metal layers; further, surface grains of the metal layers are completely oxidized by extending the action time of an electrolytic solution to form compact oxidizing layers; then, the oxidizing layers can be firmly covered on the surfaces of the metal layers so that the oxidizing layers are difficult to drop and have better insulating effect; in addition, the existing TFT adopts silicon nitride as the insulating material of the surfaces of the metal layers; to ensure the insulating property and the reliable drive of liquid crystal through capacitors among the metal layers, the dielectric constant of the material of the oxidizing layers shall be preferably close to the dielectric constant of the silicon nitride. The manufacturing method of the TFT array substrate of the present invention will be described in detail by taking Al metal layer and Al2O3 oxidizing layer as an example.

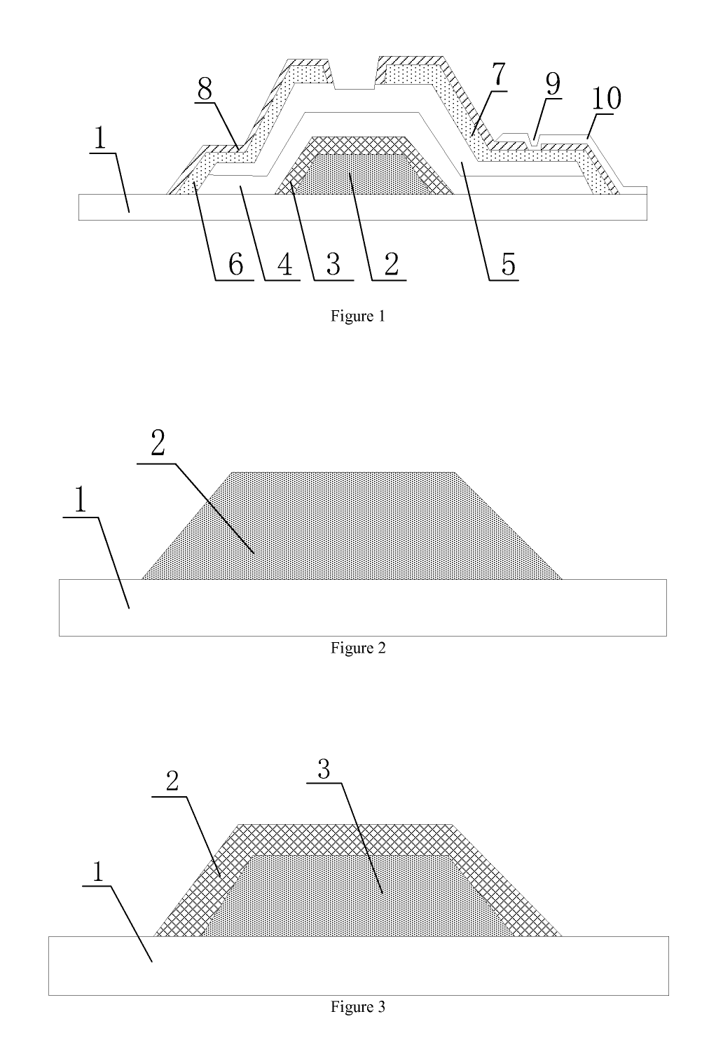

Step 1: as shown in FIG. 2, metal Al is firstly adopted on the glass substrate 1 to form the gate electrode 2;

Step 2: as shown in FIG. 3, Al2O3 is formed by oxidation on the surface of metal Al of the gate electrode 2 by the microarc oxidation method to serve as the insulating barrier, the barrier layer and the first ceramic layer 3 of the dielectric layer;

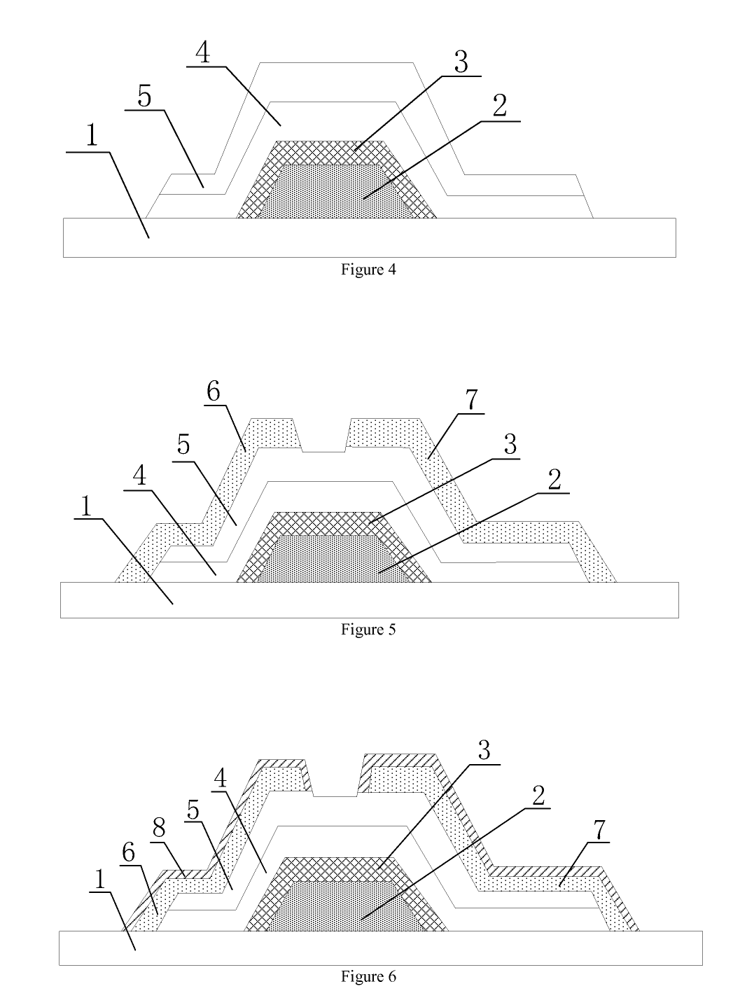

Step 3: as shown in FIG. 4, the amorphous silicon layer 4 and the doped amorphous silicon layer 5 are continuously deposited on the Al2O3 oxidizing layers of the gate electrode 2;

Step 4: as shown in FIG. 5, the source electrode and the drain electrode are deposited by metal Al on the doped amorphous silicon layer 4 and figures, such as channels and the like, are etched;

Step 5: as shown in FIG. 6, Al2O3 is formed by oxidation on the surface of metal Al of the source electrode and the drain electrode by the microarc oxidation method to serve as the insulating barrier, the barrier layer and the second ceramic layer 8 of the dielectric layer;

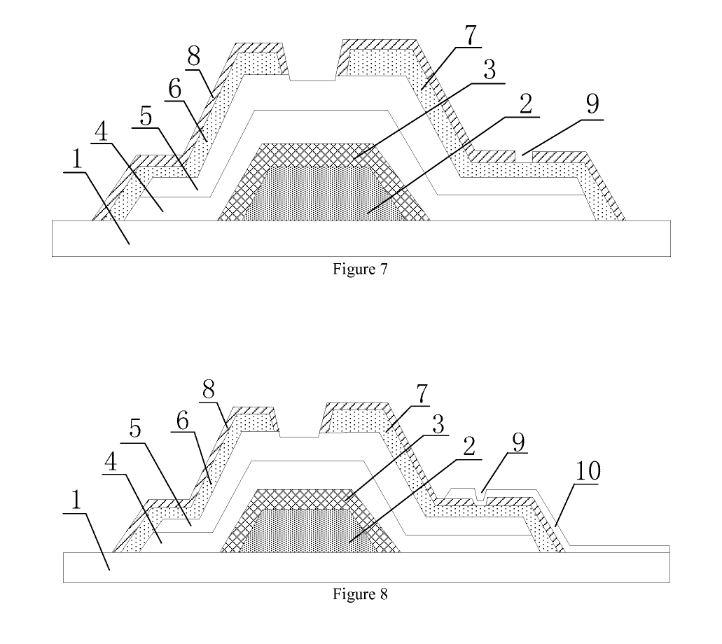

Step 6: as shown in FIG. 7, a through hole is processed on the formed ceramic layer by dry etching to form a contact window 9;

Step 7: as shown in FIG. 8, the pixel electrode 10 is deposited on the Al2O3 oxidizing layer corresponding to the drain electrode 7 and is graphed.

The present invention is described in detail in accordance with the above contents with the specific preferred examples. The metal layer of the present invention is not limited to metal Al, and accordingly, the oxidizing layer is also not limited to Al2O3; all metals with electrical conductivity and the capability of forming insulating oxidizing layers can be applied to the present invention.

The present invention CN1252321C discloses an electrolytic solution for microarc oxidation treatment of aluminum alloy cast on Apr. 19, 2006. In the present invention, the electrolytic solution can be selected for manufacturing the oxidizing layers; the specific technical proposal will not be described again; certainly, other metal oxidation technologies belong to the protection scope of the present invention. For the ordinary technical personnel of the technical field of the present invention, on the premise of keeping the conception of the present invention, the technical personnel can also make simple deductions or replacements, and all of which should be considered to belong to the protection scope of the present invention.

1. A TFT, comprising: a conductive metal layer; an insulting oxidizing layer being formed on the surface of said metal layer by oxidizing the surface of the metal layer.

2. The TFT of claim 1, wherein said metal layer is Al and said oxidizing layer is Al2O3.

3. The TFT of claim 1, wherein said metal layer is one or more of a gate electrode, a source electrode and a drain electrode of said TFT.

4. An array substrate, comprising: the TFT of claim 1; said TFT comprises a conductive metal layer; an insulting oxidizing layer being formed on the surface of said metal layer by oxidizing the surface of the metal layer.

5. The array substrate of claim 4, wherein said metal layer is Al and said oxidizing layer is Al2O3.

6. The array substrate of claim 4, wherein said metal layer is one or more of a gate electrode, a source electrode and a drain electrode of said TFT.

7. An LCD device, comprising: the array substrate of claim 4; said array substrate comprises the TFT; said TFT comprises a conductive metal layer; an insulting oxidizing layer being formed on the surface of said metal layer by oxidizing the surface of the metal layer.

8. The LCD device of claim 7, wherein said metal layer is Al and said oxidizing layer is Al2O3.

9. The LCD device of claim 7, wherein said metal layer is one or more of a gate electrode, a source electrode and a drain electrode of said TFT.

10. A TFT manufacturing method, comprising step A: processing an insulating oxidizing layer on the surface of the metal layer of a TFT array substrate, the insulating oxidizing layer being formed by oxidizing the surface of the metal layer.

11. The TFT manufacturing method of claim 10, wherein in said step A, the oxidizing layer is manufactured by a microarc oxidation method.

12. The TFT manufacturing method of claim 10, wherein in said step A, surface grains of said metal layer are completely oxidized by extending the action time of an electrolytic solution to form a compact oxidizing layer.

13. The TFT manufacturing method of claim 10, wherein in said step A, said metal layer is one or more of a gate electrode, a source electrode and a drain electrode of said TFT.

14. The TFT manufacturing method of claim 10, wherein said metal layer is Al and said oxidizing layer is Al2O3.

15. A TFT manufacturing method comprises the following steps:
A1: forming a metal TFT gate electrode on a glass substrate;
A2: adopting a microarc oxidation method to form an insulating oxidizing layer on the metal surface of said gate electrode;
A3: continuously depositing an amorphous silicon layer and a doped amorphous silicon layer on the oxidizing layer of said gate electrode;
A4: forming a source electrode and a drain electrode of the metal TFT on the doped amorphous silicon layer;
A5: adopting a microarc oxidation method for forming insulating oxidizing layers respectively on the metal surfaces of said source electrode and said drain electrode.

16. The TFT manufacturing method of claim 15, wherein further comprising a step A6: etching the insulating oxidizing layer on the metal surface of said drain electrode to form contact window for exposing part of the drain electrode.

17. The TFT manufacturing method of claim 16, wherein further comprising a step A7: forming a pixel electrode on a top surface of the insulating oxidizing layer on the metal surface of said drain electrode, the pixel electrode being connected with the drain electrode through the contact window.
